(19) United States
(12) Patent Application Publication
(10) Pub. No.: US 2017/0141204 A1
(43) Pub. Date: May 18, 2017

(54) An Array Substrate And A Method Thereof And A Display Panel Including The Same

(71) Applicant: Shenzhen China Star Optoelectronics Technology Co., Ltd., Shenzhen, Guangdong (CN)

(72) Inventor: Zhiwu WANG, Shenzhen, Guangdong (CN)

(73) Assignee: Shenzhen China Star Optoelectronics Technology Co., Ltd., Shenzhen, Guangdong (CN)

(21) Appl. No.: 14/768,008

(22) PCT Filed: Jul. 10, 2015
(86) PCT No.: PCT/CN2015/083744

§ 371 Date: Aug. 14, 2015

(30) Foreign Application Priority Data
Jun. 19, 2015 (CN) 201510346388.5

(51) Int. Cl. H01L 29/51; H01L 29/786; G02F 1/1333; H01L 21/02; G02F 1/1368; H01L 27/12; H01L 29/66

(52) U.S. Cl. CPC H01L 29/518; H01L 27/1225; H01L 29/7869; H01L 27/1259; H01L 29/66969; H01L 21/02178; H01L 21/02266; G02F 1/1368; G02F 1/133345

(57) ABSTRACT

The present invention teaches an array substrate, its manufacturing method, and a display panel using the array substrate. The array substrate contains a substrate and a number of thin film transistors (TFTs) on a top side of the substrate. Each TFT contains a gate electrode, a gate insulating layer, a channel layer, a source electrode, and a drain electrode. The gate insulating layer is between the gate electrode and the channel layer so as to prevent the conduction between the gate electrode and the channel layer. The source and drain electrodes are both on top of the channel layer. The gate insulating layer is an AlN thin film. The present invention prevents TFT threshold voltages from shifting, and guarantees the reliability of TFTs.

### BACKGROUND OF THE INVENTION

1. Field of the Invention

The present invention generally relates to display technologies, and particularly relates to an array substrate, its manufacturing method, and a display panel including the array substrate.

2. The Related Arts

For thin film transistor (TFT) display panels, the gate insulator (GI) usually employs SiO, SiN, or both. The production of SiO and SiN usually requires gases containing hydrogen. The products and the subsequently produced GI therefore inevitably contain hydrogen.

During the operation of the display panel, the TFTs can applied positive or negative bias so as to turn on or off the TFTs. The H ions in the GI/Channel interface would trap or de-trap electrons. As the display panel is operated for a period of time, and as electrons are accumulated in or released from the GI/Channel interface up to a degree, the threshold voltages of the TFTs would appear positive or negative shift, affecting the reliability of the TFTs.

### SUMMARY OF THE INVENTION

The present invention teaches an array substrate, its manufacturing method, and a display panel including the array substrate, where TFT threshold voltages are prevented from shifting, and the reliability of TFTs is guaranteed.

The present invention first provides an array substrate which contains a substrate and a number of thin film transistors (TFTs) on a top side of the substrate. Each TFT contains a gate electrode, a gate insulating layer, a channel layer, a source electrode, and a drain electrode. The gate insulating layer is between the gate electrode and the channel layer so as to prevent the conduction between the gate electrode and the channel layer. The source and drain electrodes are both on top of the channel layer. The gate insulating layer is an AlN thin film.

The AlN thin film is formed by magnetron sputtering where nitrogen gas or a gas of mixed argon and nitrogen is introduced into an Al chamber, and the AlN thin film is then formed by sputtering.

The ratio of argon to nitrogen is 0-90%.

The channel layer is made of metallic oxide.

Each TFT further contains an etch stop layer and a passivation layer. The etch stop layer is on top of the channel layer between the source and drain electrodes. The passivation layer completely covers the source and drain electrodes.

The present invention then provides a method of manufacturing an array substrate. The method contains the following steps. Firstly, a gate electrode, a gate insulating layer, a channel layer are sequentially formed on top of a substrate where the gate insulating layer is between the gate electrode and the channel layer, and the gate insulating layer is an AlN thin film. Secondly, a source electrode and a drain electrode are formed on the channel layer.

The gate insulating layer is formed by introducing nitrogen gas or a gas of mixed argon and nitrogen into an Al chamber; and forming the AlN thin film on the gate electrode by sputtering.

The ratio of argon to nitrogen is 0-90%.

When forming the AlN thin film, the temperature of the substrate is 25-300° C.

The present invention further provides a display panel. The display panel contains an array substrate. The array substrate contains a substrate and a number of TFTs on a top side of the substrate. Each TFT contains a gate electrode, a gate insulating layer, a channel layer, a source electrode, and a drain electrode. The gate insulating layer is between the gate electrode and the channel layer so as to prevent the conduction between the gate electrode and the channel layer. The source and drain electrodes are both on top of the channel layer. The gate insulating layer is an AlN thin film. The channel layer is made of metallic oxide. The AlN thin film is formed by magnetron sputtering where nitrogen gas or a gas of mixed argon and nitrogen is introduced into an Al chamber, and the AlN thin film is then formed by sputtering.

The ratio of argon to nitrogen is 0-90%.

Each TFT further contains an etch stop layer and a passivation layer. The etch stop layer is on top of the channel layer between the source and drain electrodes. The passivation layer completely covers the source and drain electrodes.

According to the present invention, AlN thin film does not contain hydrogen, therefore during the operation of the display panel, the gate insulating layer is prevented from trapping or de-trapping electrons, and the threshold voltages of the TFTs are prevented from positive or negative shift, thereby maintaining the reliability of the TFTs.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic diagram showing an array substrate according to an embodiment of the present invention;

FIG. 2 is a schematic diagram showing a display panel according to an embodiment of the present invention;

FIG. 3 is a schematic diagram showing a method of manufacturing an array substrate according to an embodiment of the present invention.

### DETAILED DESCRIPTION OF THE PREFERRED EMBODIMENTS

FIG. 1 is a schematic diagram showing an array substrate according to an embodiment of the present invention. As illustrated, an array substrate 100 contains a substrate 110 and a number of thin film transistors (TFTs) 120 on a top side of the substrate 110 (FIG. 1 only shows a single TFT 120 as example). The substrate 110 is a glass substrate or a transparent substrate made of other insulating material. The TFT 120 contains a gate electrode 121, a gate insulating layer 122, a channel layer 123, a source electrode 124, and a drain electrode 125. The gate electrode 121 is on the top side of the substrate 110. The gate insulating layer 122 is between the gate electrode 121 and the channel layer 123 so as to prevent the conduction between the gate electrode 121 and the channel layer 123. The source and drain electrodes 124 and 125 are both on top of channel layer 123 without contacting each other. When the gate electrode 121 is applied a voltage greater than or equal to the threshold voltage, electrons are induced from the channel layer 123, thereby conducting the source and drain electrodes 124 and 125.

The gate insulating layer 122 is an aluminum nitride (AlN) thin film. The AlN thin film is an excellent insulating material, therefore providing superior insulation between the gate electrode 121 and the channel layer 123. In addition, the AlN thin film has high breakdown field strength (1.2-1.8 MV/cm for AlN crystal), high thermal conductivity, high chemical and thermal stability, and over 90% penetration rate within the visible light range. Furthermore, the AlN thin film does not contain hydrogen, therefore during the operation of the display panel, the gate insulating layer is prevented from trapping or de-trapping electrons, and the threshold voltages of the TFTs are prevented from positive or negative shift, thereby maintaining the reliability of the TFTs.

In the present embodiment, the channel layer 123 is made of metallic oxide such as indium gallium zinc oxide (IGZO).

The TFT 120 can further contains an etch stop layer 126 and a passivation layer 127. The etch stop layer 125 is on top of the channel layer 123 between the source and drain electrodes 124 and 125. The passivation layer 127 completely covers the source and drain electrodes 124 and 125, and the etch stop layer 126.

In an alternative embodiment, a silicide layer is configured among the source electrode, the drain electrode and the passivation layer so as to prevent Cu ions diffuse from the source and drain electrodes into the passivation layer.

In the above described structure, the gate electrode 121, the channel layer 123, the source electrode 124, and the drain electrode 125 can formed by physical vapor deposition (PVD). The etch stop layer 126 and the passivation layer 127 can be formed by plasma enhanced chemical vapor deposition (PECVD).

The gate insulating layer 122, i.e., AlN thin film, can be formed by etching using inductively coupled plasma (ICP) apparatus, or PVD such as magnetron sputtering.

In an embodiment where the AlN thin film is formed by magnetron sputtering, nitrogen gas or a gas of mixed argon and nitrogen is introduced into an Al chamber, and the AlN thin film is then formed by sputtering. The ratio of argon to nitrogen is 0-90% such as 0%, 45%, or 90%.

During magnetron sputtering, the temperature of the substrate is 25-300° C. such as 25, 85, or 300° C. In other words, the formation of the AlN thin film using magnetron sputtering can be conducted under room temperature. In addition, no oxidative gas is involved and therefore the oxidation of gate electrode can be prevented when depositing gate insulating layer.

The etch stop layer 126 can also be an AlN thin film whose formation is similar to what is described above. As the AlN thin film does not contain hydrogen, therefore when the etch stop layer is formed, the channel layer is prevented from reduction, or pores are prevented from occurring in the etch stop layer, even when the temperature is too high or too low. The quality of the TFTs is as such guaranteed. In other words, there is little temperature requirement when forming the AlN thin film, reducing the film formation complexity and increasing the speed of formation.

In yet another embodiment, the array substrate can further contains a number of data lines, scan lines, and pixel electrodes (not shown). The data lines are connected to the source electrodes of the TFTs, the scan lines are connected to the gate electrodes of the TFTs, and the pixel electrodes are connected to the drain electrodes of the TFTs. When a voltage greater than or equal to the threshold voltage is applied to the gate electrodes of the TFTs through the scan lines, the source and drain electrodes of the TFTs are conducted. The data lines are connected to the pixel electrodes, and the pixel electrodes receive the voltage from the data lines.

In order to increase the pixel electrodes' aperture ratio, the source electrode, the drain electrode, and the pixel electrodes are integrally formed using transparent conductive thin film.

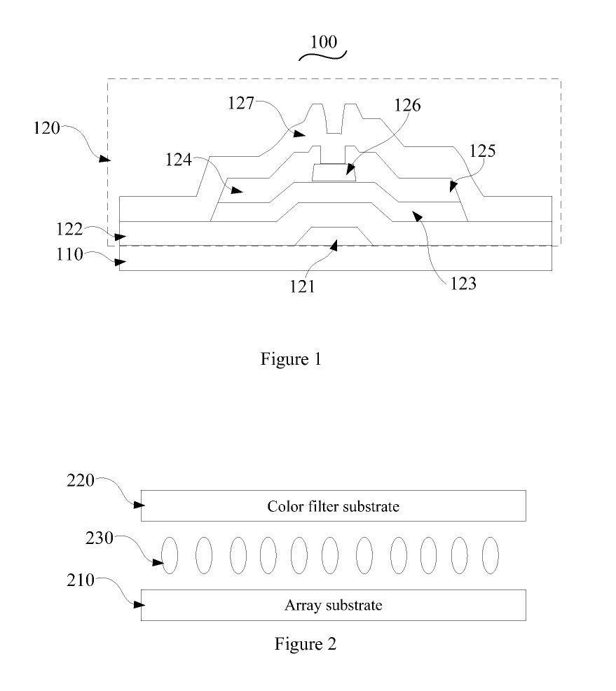

FIG. 2 is a schematic diagram showing a display panel according to an embodiment of the present invention. As illustrated, a display panel contains an array substrate 210, a color filter (CF) substrate 220, and liquid crystal molecules 230 between the array and CF substrates 210 and 220. The array substrate 210 is described above. The CF substrate 220 can contain a substrate and, on top of the substrate, a black matrix, a CF layer, a protection layer, and an ITO film. When the pixel electrodes of the array substrate receive display voltage from the data lines, an electrical field is formed between the array substrate and the ITO film of the CF substrate, which drives the liquid crystal molecules 230 to turn to display image.

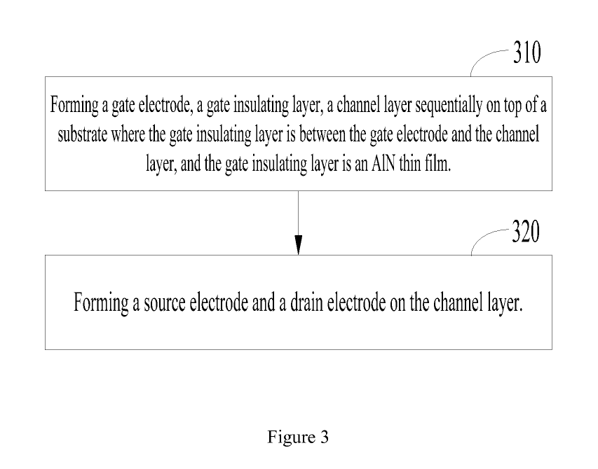

FIG. 3 is a schematic diagram showing a method of manufacturing an array substrate according to an embodiment of the present invention. The method contains the following steps.

In step 310, a gate electrode, a gate insulating layer, a channel layer are formed on a substrate. The gate insulating layer is between the gate electrode and the channel layer. The gate insulating layer is an AlN thin film.

In the present embodiment, the gate electrode is formed on the substrate. The gate electrode is covered by the AlN thin film as the gate insulating layer. The channel layer is then formed on the gate insulating layer. The gate electrode and the channel layer can be formed using PVD.

The AlN thin film can be formed by etching using inductively coupled plasma (ICP) apparatus or PVD such as magnetron sputtering. For the latter, nitrogen gas or a gas of mixed argon and nitrogen is introduced into an Al chamber, and the AlN thin film is then formed by sputtering. The ratio of argon to nitrogen is 0-90% such as 0%, 45%, or 90%. During magnetron sputtering, the temperature of the substrate is 25-300° C. such as 25, 85, or 300° C. The formation of the AlN thin film using magnetron sputtering therefore can be conducted under room temperature. In addition, no oxidative gas is involved and therefore the oxidation of gate electrode can be prevented when depositing gate insulating layer.

In step 320, a source electrode and a drain electrode are formed on the channel layer.

After forming the channel layer, the source and drain electrodes are separately formed on the channel layer. The source and drain electrodes do not contact each other. Optionally, an etch stop layer can be formed on top of the channel layer between the source and drain electrodes. In addition, a passivation layer completely covering the source and drain electrodes can be formed.

Specifically, the source and drain electrodes can formed by PVD. The etch stop layer and the passivation layer can be formed by PECVD. Alternatively, the etch stop layer can also be an AlN thin film using similar PVD method for forming the gate insulating layer in step 310.

In another embodiment, the above method also includes forming a number of data lines, scan lines, and pixel electrodes on the substrate. The data lines are connected to the source electrodes of the TFTs, the scan lines are connected to the gate electrodes of the TFTs, and the pixel electrodes are connected to the drain electrodes of the TFTs.

As the AlN thin film is used as the gate insulating layer for the array substrate's TFTs, and the AlN thin film does not contain hydrogen, therefore during the operation of the display panel, the gate insulating layer is prevented from trapping or de-trapping electrons, and the threshold voltages of the TFTs are prevented from positive or negative shift, thereby maintaining the reliability of the TFTs.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A display panel comprising an array substrate wherein the array substrate comprises a substrate and a plurality of thin film transistors (TFTs) on a top side of the substrate; each TFT comprises a gate electrode, a gate insulating layer, a channel layer, a source electrode, and a drain electrode; the gate insulating layer is between the gate electrode and the channel layer so as to prevent the conduction between the gate electrode and the channel layer; the source and drain electrodes are both on top of the channel layer; the gate insulating layer is an AlN thin film; the channel layer is made of metallic oxide; and the AlN thin film is formed by magnetron sputtering where nitrogen gas or a gas of mixed argon and nitrogen is introduced into an Al chamber, and the AlN thin film is then formed by sputtering.

2. The display panel as claimed in claim 1, wherein the ratio of argon to nitrogen is 0-90%.

3. The display panel as claimed in claim 1, wherein each TFT further comprises an etch stop layer and a passivation layer; the etch stop layer is on top of the channel layer between the source and drain electrodes; and the passivation layer completely covers the source and drain electrodes.

4. An array substrate comprising a substrate and a plurality of thin film transistors (TFTs) on a top side of the substrate, wherein each TFT comprises a gate electrode, a gate insulating layer, a channel layer, a source electrode, and a drain electrode; the gate insulating layer is between the gate electrode and the channel layer so as to prevent the conduction between the gate electrode and the channel layer; the source and drain electrodes are both on top of the channel layer; and the gate insulating layer is an AlN thin film.

5. The array substrate as claimed in claim 4, wherein the AlN thin film is formed by magnetron sputtering where nitrogen gas or a gas of mixed argon and nitrogen is introduced into an Al chamber, and the AlN thin film is then formed by sputtering.

6. The array substrate as claimed in claim 5, wherein the ratio of argon to nitrogen is 0-90%.

7. The array substrate as claimed in claim 4, wherein the channel layer is made of metallic oxide.

8. The array substrate as claimed in claim 4, wherein each TFT further comprises an etch stop layer and a passivation layer; the etch stop layer is on top of the channel layer between the source and drain electrodes; and the passivation layer completely covers the source and drain electrodes.

9. A method of manufacturing an array substrate, comprising the steps of:
forming a gate electrode, a gate insulating layer, a channel layer sequentially on top of a substrate where the gate insulating layer is between the gate electrode and the channel layer, and the gate insulating layer is an AlN thin film; and
forming a source electrode and a drain electrode on the channel layer.

10. The method as claimed in claim 9, wherein the gate insulating layer is formed by introducing nitrogen gas or a gas of mixed argon and nitrogen into an Al chamber; and forming the AlN thin film on the gate electrode by sputtering.

11. The method as claimed in claim 10, wherein the ratio of argon to nitrogen is 0-90%.

12. The method as claimed in claim 10, wherein, when forming the AlN thin film, the temperature of the substrate is 25-300° C.
